(19) United States
(12) Patent Application Publication
(10) Pub. No.: US 2014/0175963 A1
(43) Pub. Date: Jun. 26, 2014

(54) CASE ASSEMBLY

(71) Applicant: GIGA-BYTE TECHNOLOGY CO., LTD., New Taipei City (TW)

(72) Inventors: Ching Wen Wang, New Taipei City (TW); Meng Fu Lu, New Taipei City (TW)

(73) Assignee: GIGA-BYTE TECHNOLOGY CO., LTD., New Taipei City (TW)

(21) Appl. No.: 13/785,299

(22) Filed: Mar. 5, 2013

(30) Foreign Application Priority Data
Dec. 26, 2012 (TW) TW101150214

(51) Int. Cl. H05K 5/02; A47B 96/00

(52) U.S. Cl. CPC H05K 5/0226; A47B 96/00
USPC 312/325

(57) ABSTRACT

A case assembly includes an upper case, a lower case, a pivot, a first shaft, a second shaft, and a stopper. The pivot is pivotally connected to the lower case, such that the upper case is able to rotate with respect to the lower case. The stopper has a shaft hole, a guiding slot hole, and a fixing slot hole. The shaft hole is disposed at one end of the stopper, and fixing slot hole is disposed at the other end of the stopper. The fixing slot hole communicates with the guiding slot hole. The first and the second shafts respectively insert into the shaft hole and the guiding slot hole. When the upper case rotates with respect to the lower case, the second shaft is stuck in the fixing slot hole from the guiding slot hole.

### CROSS-REFERENCES TO RELATED APPLICATIONS

This non-provisional application claims priority under 35 U.S.C. §119(a) on Patent Application No. 101150214 filed in Taiwan, R.O.C. on Dec. 26, 2012, the entire contents of which are hereby incorporated by reference.

### BACKGROUND

1. Technical Field

This disclosure relates to a case assembly, and more particularly to a case assembly with a stopper

2. Related Art

With the advance in the electronics industry, the function and appearance of the consumer electronics gradually becomes a key factor about marketing. For mature electronic products, simple design becomes the main consideration for consumers. Take personal computer as an example, due to the limited difference of most personal computers, the design of case assemblies gradually become a focus on product development. With more beautiful appearance and more convenient operation method, the product is more likely to become the mainstream choice for the consumers.

A common case assembly is divided into an upper case and a lower case, when the user wants to look up or replace the computer parts, the upper case is drawn away from rear side of the computer. When combining, the user should push the upper case into the lower case and use screws to fix the upper case and the lower case. The separation of the upper case and the lower case brings about much inconvenience, and some inconvenience may be generated if the screws are lost. Therefore, the user will spend a lot of time separating the case assembly. If the screwdriver and the screws can not fit with each other, it will become more difficult to separate the upper case and the lower case.

A case assembly, which can be opened or assembled without using any screws, is proposed. Beside the upper case and the lower case, such a case assembly further has an auxiliary piece to connect the upper case and the lower case. This case assembly solves the issue that removing or inserting screws are required when users open or close the case assembly, such that the assembling is troublesome and time-consuming.

The above case assembly does improve the convenience about the assembling, but the case assembly doesn't have fixing device for safety. When the upper case is separated from the lower case, it is possible that users may get injured due to the accidental closure of the upper case and the lower case. Besides, for avoiding the accidental closure of the upper case and the lower case, users need to withstand the upper case while in maintenance, resulting in slow maintenance, increased labor costs, and other issues.

Therefore, making the upper case fixed while the upper case is separated from the lower case and improving stopping function of the flip structure to enhance the safety and the maintenance convenience is an important issue.

### SUMMARY OF THIS DISCLOSURE

In view of the above problems, this disclosure provides a case assembly, so as to solve the issue that conventional case assembly does not include the fixing device for safety, such that users may get injured due to the accidental closure of the upper case and the lower case.

The case assembly includes an upper case, a lower case, a pivot, a first shaft, a second shaft, and a stopper. The pivot inserts into the upper case and the lower case, so as to connect the upper case and the lower case. The upper case is disposed on the lower case, and the upper case is able to rotate with respect to the lower case with the pivot as the rotation axis, so that the upper case is able to be opened or closed with respect to the lower case. The first shaft is connected to the upper case, and the second shaft is connected to the lower case. The axial directions of the first and second shaft are parallel to the axial direction of the pivot. The stopper includes a shaft hole, a guiding slot hole, and a fixing slot hole, and the stopper further includes a first end and a second end connecting with each other. The shaft hole, the guiding slot hole, and the fixing slot hole all run through the stopper. The shaft hole is disposed at the first end, and the fixing slot hole is disposed at the second end. One end of the fixing slot hole communicates with the guiding slot hole, and the fixing slot hole and the guiding slot hole form an angle. The first shaft and the second shaft respectively insert into the shaft hole and the guiding slot hole.

When the upper case rotates with respect to the lower case, the stopper takes the first shaft as the rotation axis to rotate, and the guiding slot hole moves with respect to the second shaft, so that the second shaft is stuck in the fixing slot hole from the guiding slot hole and that the upper case is fixed in an opened position.

The case assembly is able to be fixed when the upper case is opened by the structure of the guiding slot hole and the fixing slot hole, such that the maintenance safety is improved and that the labor cost is reduced.

The detail of this disclosure can be better appreciated from the following detailed description of this disclosure, taken in conjunction with the attached drawings.

### BRIEF DESCRIPTION OF THE DRAWINGS

This disclosure will become more fully understood from the detailed description given herein below for illustration only, and thus not limitative of this disclosure, wherein:

FIG. 1 is an exploded view of the case assembly according to a first embodiment.

FIG. 2 is a partial exploded view of the case assembly according to the first embodiment.

FIG. 3 is a perspective view of the case assembly according to the first embodiment.

FIG. 4 is a partial plan view of the case assembly while the upper case is opened according to the first embodiment.

FIG. 5 is a partial plan view of the case assembly when the second shaft leaves the fixing slot hole.

FIG. 6 is a perspective view of the case assembly according to the first embodiment.

FIG. 7 is a partial plan view of the case assembly while the upper case is closed according to the first embodiment.

FIG. 8 is a partial plan view of the case assembly according to a second embodiment.

### DETAILED DESCRIPTION OF THE DISCLOSURE

A case assembly 100 disclosed in this disclosure takes a personal computer as an illustration. People having ordinary skill in the art can make proper modification to the appearance and the function of the case assembly 100 according to the actual needs or design requirements, not limited as described herein.

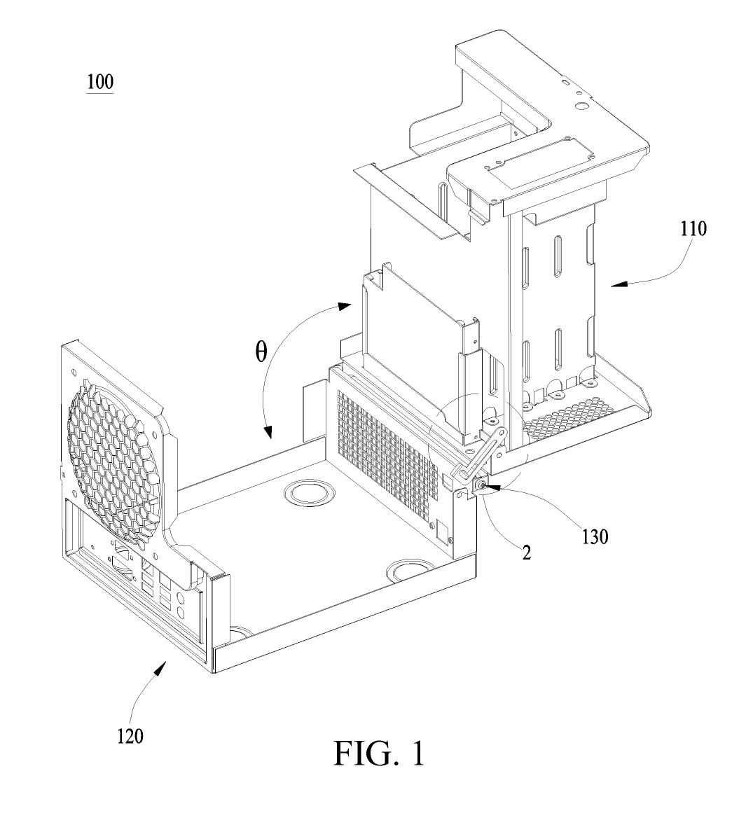

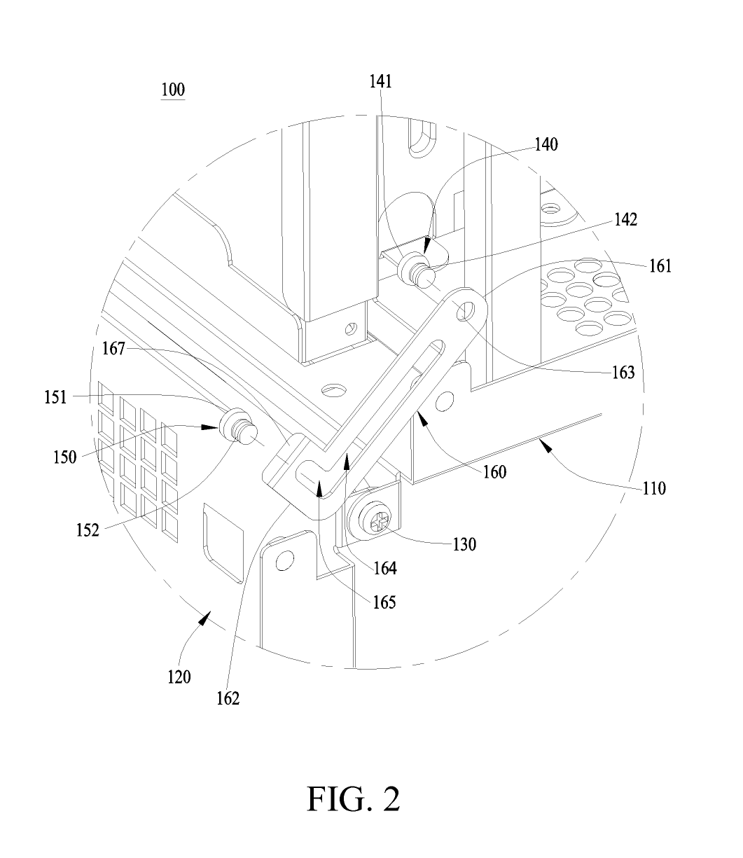

Refer to FIG. 1 and FIG. 2, a motherboard and associated computer components can be installed inside the upper case 110 and the lower case 120 described in this embodiment, such as a CD-ROM drive, a graphics card, or hard drives. The associated computer components are similar to those in the prior art, so the inventor will not describe here. The followings will describe in detail only about the case assembly.

The case assembly 100 includes an upper case 110, a lower case 120, a pivot 130, a first shaft 140, a second shaft 150, and a stopper 160. The pivot 130 inserts into the upper case 110 and the lower case 120, so that the upper case 110 and the lower case 120 are connected with each other. The upper case 110 is disposed on the lower case 120, and the upper case 110 takes the pivot 130 as the rotation axis to rotate an angle θ with respect to the lower case 120, such that the upper case 110 is opened or closed. The shapes of the first shaft 140 and the second shaft 150 are cylindrical. The first shaft 140 is connected to the upper case 110, and the second shaft 150 is connected to the lower case 120. The axial directions of the first shaft 140 and the second shaft 150 are parallel to that of the pivot 130. The stopper 160 runs through the first shaft 140 and the second shaft 150.

Further explain the structure of the stopper 160. The stopper 160 has a first end 161, a second end 162 connected to the first end 161, a shaft hole 163, a guiding slot hole 164, and a fixing slot hole 165. The shape of the stopper 160 is L-shaped, not limited as described herein, and the shaft hole 163, the guiding slot hole 164, and the fixing slot hole 165 all run through the stopper 160. The shaft hole 163 is disposed at the first end 161 of the stopper 160, and the shape of the shaft hole 163 corresponds to that of the first shaft 140. The guiding slot hole 164 is disposed at the second end 162, and the width of the guiding slot hole 164 corresponds to the diameter of the second shaft 150. The length of the guiding slot hole 164 equals the length of rotation path of the upper case 110 and corresponds to the rotation angle θ of the upper case 110. One end of the fixing slot hole 165 communicates the guiding slot hole 164, and an angle is formed between the fixing slot hole 165 and the guiding slot hole 164. The first shaft 140 connected to the upper case 110 inserts into the shaft hole 163, and the second shaft 150 connected to the lower case 120 inserts into the guiding slot hole 164.

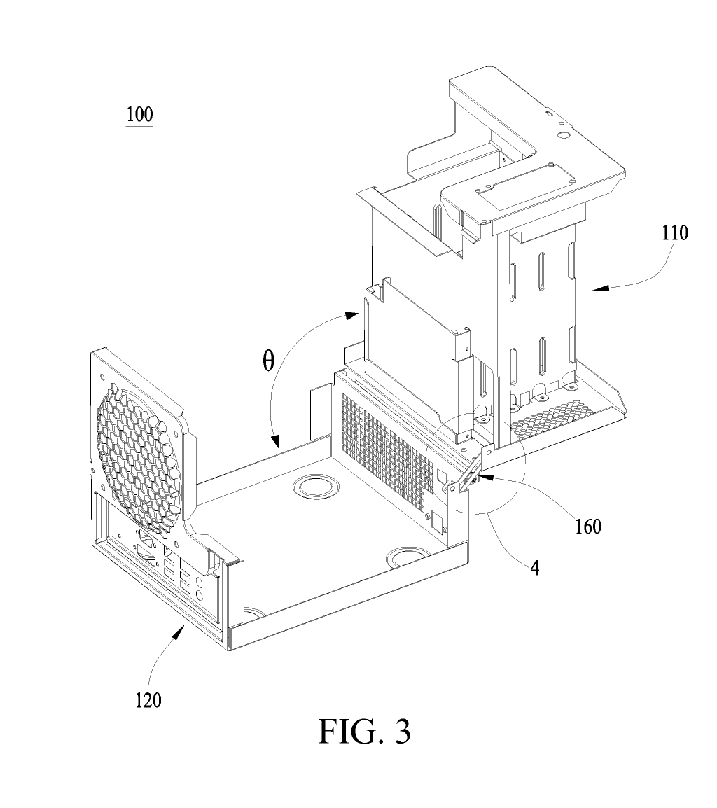

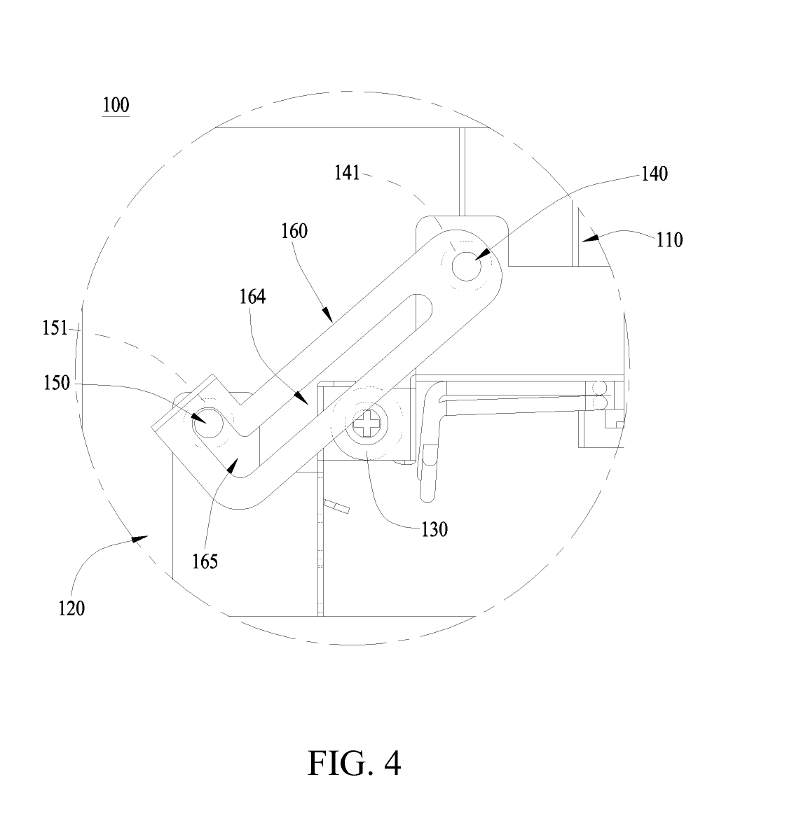

Refer to FIG. 3 and FIG. 4. When the upper case 110 takes the pivot 130 as the rotation axis to rotate an angle θ with respect to the lower case 120, the stopper 160 is driven to rotate with the first shaft 140 as the rotation axis, and the guiding slot hole 164 moves as well with respect to the second shaft 150, such that the second shaft 150 slides along the guiding slot hole 164 and that the second shaft 150 slides into the end with the fixing slot hole 165 from the guiding slot hole 164 when the rotation angle θ is greater than 90 degree. Because the opening angle of the upper case 110 is greater than 90 degree, the second shaft 150 will slide into the fixing slot hole 165 by the weight of the upper case 160, such that the upper case 110 is fixed to an opened position.

The rotation angle θ is set to be greater than 90 degree when the upper case 110 is fixed to the opened position, for avoiding the upper case 110 accidentally falling due to the weight thereof. The second shaft 150 is also not easy to fixed in the fixing slot hole 165 if the rotation angle θ is smaller than 90 degree. However, it is not necessary to make the rotation angle θ greater than 90 degree. People having ordinary skill in the art can make proper modification to the rotation angle θ when the upper case is fixed to the opened position case 100 according to the actual needs or design requirements, not limited as described herein.

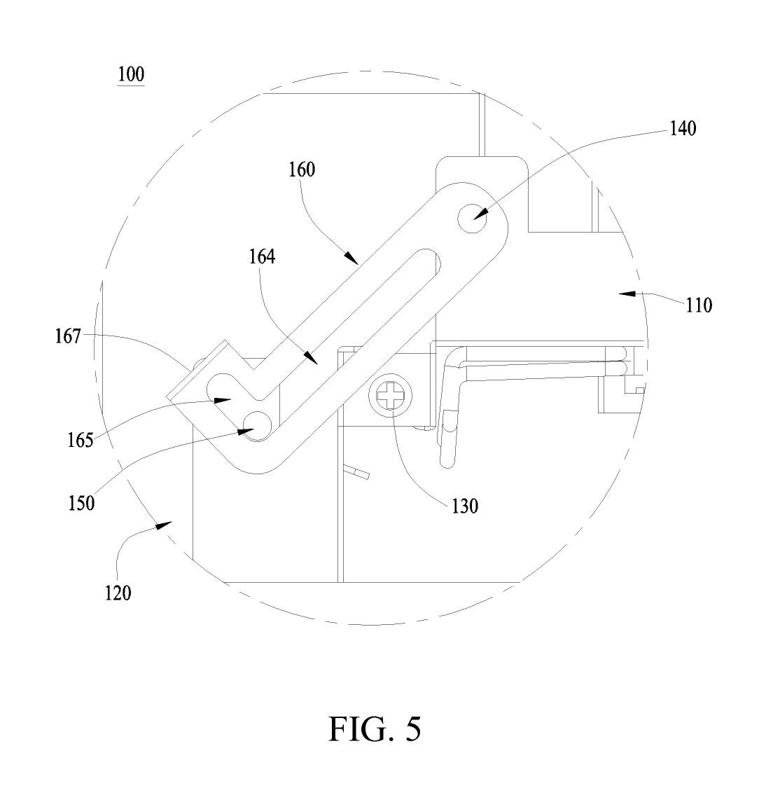

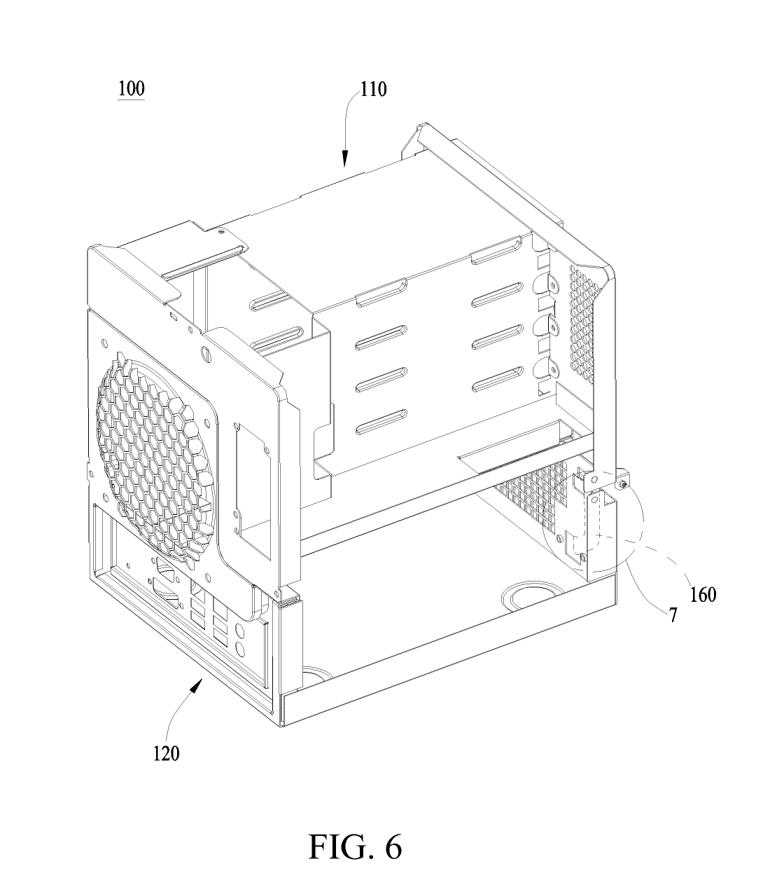

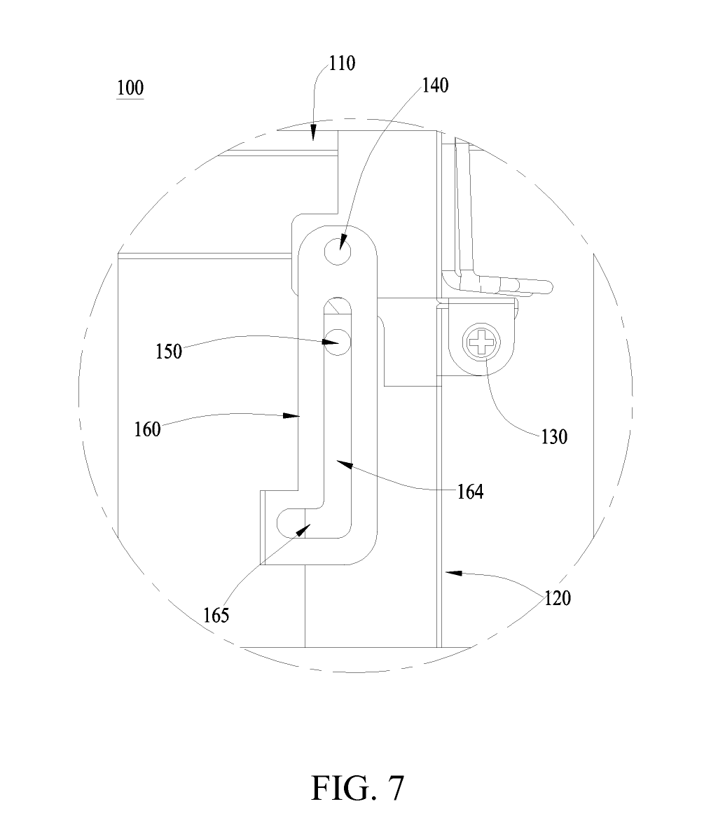

Refer to FIG. 5 to FIG. 7, when the stopper 160 is lifted and the second shaft 150 leaves the fixing slot hole 165, the second shaft 150 slides along the guiding slot hole 164 and toward the direction of the shaft hole 163, and the stopper 160 is driven to rotate with the pivot 130 as the rotation axis, such that the stopper 160 get back to the initial position and that the upper case 110 covers the lower case 120 again.

Refer to FIG. 2 as well, the first shaft 140 and the second shaft 150 both have a cam 141 and 151 and a screw thread portion 142 and 152. These cams 141 and 151 are connected to one end of these shafts 140 and 150, and the outer diameters of these the cams 141 and 151 are larger than the diameters of the shafts 140 and 150. The first shaft 140 and the second shaft 150 insert into the shaft hole 163 and the guiding slot hole 164 respectively by the screw thread portion 142 and 152, such that the stopper 160 is fixed to the upper case 110 and the lower case 120. The stopper 160 withstands these cams 141 and 151 as well, in order to avoid the stopper 160 slips out of these shaft 140 and 150 while actuating and to fix the stopper 160.

For better operability, the stopper 160 further has a handle 167 disposed at the second end 162 and extends perpendicular to the direction of the stopper 160 and toward the interior of the lower case 120. Via the handle 167, users can easily lift the stopper 160, so that the second shaft 150 leaves the fixing slot hole 165 easily and quickly.

The case assembly is able to be fixed when the upper case is opened by the structure of the guiding slot hole and the fixing slot hole, and the case assembly will not fall by accidental collisions, such that the maintenance safety is improved and that the labor cost is reduced.

Besides, this disclosure further includes a handle, so that users can easily lift the stopper and make the second shaft leave the fixing slot hole easily and quickly, enhancing the operability.

The structure of a case assembly 100 according to the second embodiment is similar to that of the case assembly 100 according to the first embodiment, so the inventor will only describe differences in detail.

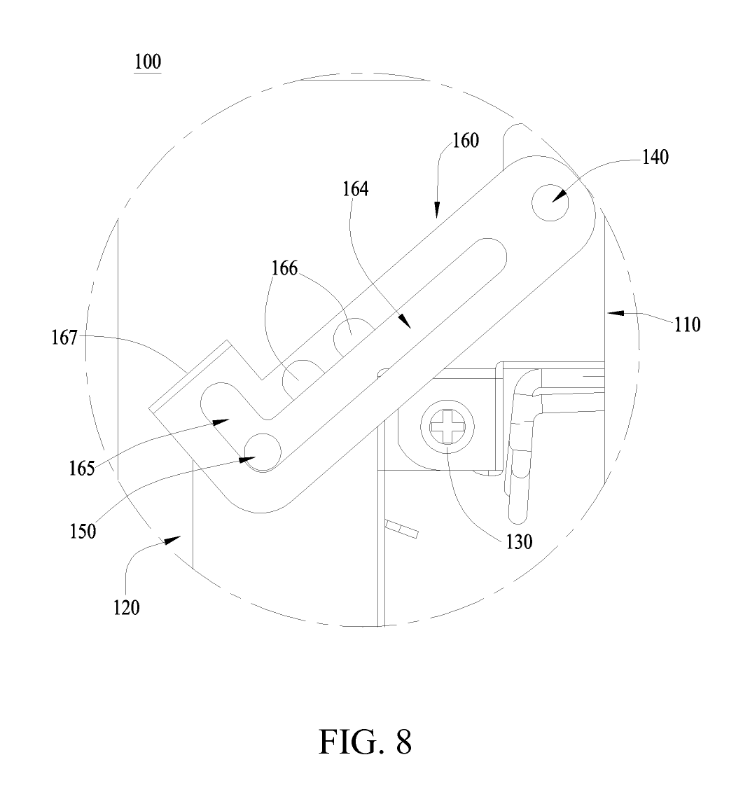

Refer to FIG. 8, the case assembly 100 includes an upper case 110, a lower case 120, a pivot 130, a first shaft 140, a second shaft 150, and a stopper 160. The pivot 130 inserts into the upper case 110 and the lower case 120, so that the upper case 110 and the lower case are connected to each other. The upper case 110 is disposed on the lower case 120, and the upper case 110 is able to rotate an angle θ with respect to the lower case 120 with the pivot 130 as the rotation axis, such that the upper case 110 is opened or closed. The shapes of the first shaft 140 and the second shaft 150 are cylindrical. The first shaft 140 is connected to the upper case 110, and the second shaft 150 is connected to the lower case 120. The axial directions of the first shaft 140 and the second shaft 150 are parallel to the axial direction of the pivot 130. The stopper 160 runs through the first shaft 140 and the second shaft.

Further explain the structure of the stopper 160. The stopper 160 has a first end 161, a second end 162 connected to the first end 161, a shaft hole 163, a guiding slot hole 164, and a fixing slot hole 165. The shape of the stopper 160 is L-shaped, and the shaft hole 163, the guiding slot hole 164, and the fixing slot hole 165 all run through the stopper 160. The shaft hole 163 is disposed at the first end 161 of the stopper 160, and the shape of the shaft hole 163 corresponds to that of the first shaft 140. The guiding slot hole 164 is disposed at the second end 162, and the width of the guiding slot hole 164 corresponds to the diameter of the second shaft 150. One end of the fixing slot hole 165 communicates the guiding slot hole 164, and an angle is formed between the fixing slot hole 165 and the guiding slot hole 164. The first shaft 140 connected to the upper case 110 inserts into the shaft hole 163, and the second shaft 150 connected to the lower case 120 insert into the guiding slot hole 164.

The difference between the case assembly 100 according to the first embodiment and the case assembly 100 according to the second embodiment is that the stopper 160 according to the second embodiment has a plurality of notches 166 interval disposed in the stopper 160 and communicating to the guiding slot hole 164. The second shaft 150 is selectively fixed to one of the notches 166 corresponding to the rotation angle of the upper case 110 with respective to the lower case, such that the upper case 110 is able to be fixed to different angles.

The case assembly 100 is able to be fixed in different angles when the upper case 110 is opened by the structure of a plurality of notches 166 of the stopper 160, so that users can adjust according to their operation needs, enhancing the operation convenience.

Though the embodiments of this disclosure are disclosed as described above, this is not to limit this disclosure. People having ordinary skill in the art will recognize that this disclosure can be practiced with modification within the spirit and scope of the claim. It is therefore to be understood that this disclosure is not to be limited by the foregoing description but only by the appended claims.

1. A case assembly, comprising:
an upper case and a lower case;
a pivot, respectively connected the upper case and the lower case, wherein the upper case is arranged to rotate with respect to the lower case, with the pivot as the rotation axis;
a first shaft, disposed in the upper case;
a second shaft, disposed in the lower case, wherein the axial directions of the first shaft and the second shaft are parallel to the axial direction of the pivot;
a stopper, including a shaft hole running through the stopper, a guiding slot hole, and a fixing slot hole, wherein the stopper includes a first end and a second end connected to each other, the shaft hole is disposed at the first end, the fixing slot hole is disposed at the second end, one end of the fixing slot hole communicates with the guiding slot hole, the fixing slot hole and the guiding slot hole define an included angle, and the first shaft and the second shaft respectively insert into the shaft hole and the guiding slot hole;
a plurality of notches interval disposed in the stopper and communicating to the guiding slot hole;
wherein when the upper case rotates with respect to the lower case, the stopper takes the first shaft as the rotation axis to rotate, and the guiding slot hole are driven to move with respect to the second shaft, so that the second shaft is selectively stuck in the fixing slot hole or one of the notches from the guiding slot hole and that the upper case is fixed to different angles.

2. (canceled)

3. The case assembly as claimed in claim 1, wherein the rotation angle of the upper case is greater than 90 degree.

4. The case assembly as claimed in claim 1, wherein the shapes of the first shaft and the second shaft are cylindrical, the shape of the shaft hole corresponds to the first shaft, and the width of the guiding slot hole corresponds to the diameter of the second shaft.

5. The case assembly as claimed in claim 1, wherein both of the first shaft and the second shaft have a circular flange and a screw thread portion connecting to the circular flange, the outer diameters of the circular flanges are larger than diameters of the other section of the two shafts, these the first shaft and the second shaft are respectively fixed to the upper case and the lower case by the corresponding screw thread portions, and the stopper withstands the circular flanges.

6. The case assembly as claimed in claim 1, wherein the shape of the stopper is L-shaped.

7. The case assembly as claimed in claim 1, wherein the second end of the stopper further has a handle.

8. The case assembly as claimed in claim 1, wherein the length of the guiding slot hole corresponds to the length of the rotation path of the upper case.
